(19) United States
(12) Patent Application Publication
(10) Pub. No.: US 2025/0347947 A1
(43) Pub. Date: Nov. 13, 2025

(54) DISPLAY DEVICE

(71) Applicant: SAMSUNG ELECTRONICS CO., LTD., Suwon-si (KR)

(72) Inventors: Yeonho KIM, Suwon-si (KR); Kyungbae KIM, Suwon-si (KR); Beomhan KIM, Suwon-si (KR); Sunjin KIM, Suwon-si (KR)

(73) Assignee: SAMSUNG ELECTRONICS CO., LTD., Suwon-si (KR)

(21) Appl. No.: 19/274,941

(22) Filed: Jul. 21, 2025

Related U.S. Application Data
(63) Continuation of application No. PCT/KR2024/095025, filed on Jan. 12, 2024.

(30) Foreign Application Priority Data
Mar. 10, 2023 (KR) 10-2023-0032055
Apr. 24, 2023 (KR) 10-2023-0053599
Aug. 9, 2023 (KR) 10-2023-0104238

(51) Int. Cl. G02F 1/1333

(52) U.S. Cl. CPC G02F 1/133314; G02F 1/13332; G02F 1/133325; G02F 1/133382

(57) ABSTRACT

This display device comprises: a display panel; a front chassis to extend along a perimeter of the display panel to cover side surfaces of the display panel; a rear chassis provided to cover the rear surface of the display panel; and a chassis connection member connectable to the rear chassis so that while the chassis connecting member and the rear chassis are connected, the chassis connecting member couples the rear chassis to the front chassis. The chassis connection member is coupleable to the front chassis to thereby couple the rear chassis to the front chassis by being slid with respect to the lower side surface of the front chassis so as to be coupled to the front chassis without requiring a separate fastening member.

### CROSS-REFERENCE TO RELATED APPLICATION

This application is a continuation application is a continuation application, under 35 U.S.C. § 111 (a), of international application No. PCT/KR2024/095025, filed Jan. 12, 2024, which claims priority under 35 U. S. C. § 119 to Korean Patent Application No. 10-2023-0032055, filed Mar. 10, 2023, Korean Patent Application No. 10-2023-0053599, filed Apr. 24, 2023, Korean Patent Application No. 10-2023-0104238, filed Aug. 9, 2023, the disclosures of which are incorporated herein by reference in their entireties.

### TECHNICAL FIELD

The present disclosure relates to a display device.

### BACKGROUND ART

In general, a display device is a kind of output device that converts acquired or stored electrical information into visual information to display the visual information for users. The display device is used in various fields, such as home or places of business.

The display device is classified into a self-emissive type including a self-emissive display panel such as Organic Light emitting Diode (OLED) which itself emits light, and a non-emissive type using a display panel such as a Liquid Crystal Display (LCD) which receives light from a backlight unit without itself emitting light.

Generally, to assemble a display device, fastening members such as screws are exposed on the bottom of the display device. The fastening members exposed on the bottom of the display device may deteriorate the design of the display device.

### DISCLOSURE

### Technical Problem

An aspect of the present disclosure provides a display device having an improved aesthetic sense because no fastening member is exposed on a lower surface.

The technical object intended to be achieved by the present document is not limited to the above-mentioned technical objects, and other technical objects not mentioned will be clearly understood by one of ordinary skill in the technical art to which the disclosure belongs from the following description.

### Technical Solution

A display device according to a concept of the present disclosure may include a display panel, a front chassis to extend along a perimeter of the display panel and to cover sides of the display panel, a rear chassis to cover a rear surface of the display panel, and a chassis connecting member connectable to the rear chassis so that while the chassis connecting member and the rear chassis are connected, the chassis connecting member couples the rear chassis to the front chassis. The chassis connecting member is coupleable to the front chassis to thereby couple the rear chassis to the front chassis by being slid on a lower side of the front chassis without requiring a separate fastening member.

A display device according to a concept of the present disclosure may include a liquid crystal panel, a front chassis to extend along a perimeter of the liquid crystal panel and to cover sides of the liquid crystal panel, a rear chassis to cover a rear surface of the liquid crystal panel, a backlight unit configured to supply light to the liquid crystal panel and be accommodated between the liquid crystal panel, the front chassis, and the rear chassis, and a chassis connecting member coupled to the front chassis. The chassis connecting member may be coupled to the front chassis by being slid on a lower side of the front chassis without requiring a separate fastening member.

### DESCRIPTION OF DRAWINGS

FIG. 1 is a front perspective view of a display device according to an embodiment.

FIG. 2 is a rear perspective view of a display device according to an embodiment.

FIG. 3 is a front exploded perspective view of a display device according to an embodiment.

FIG. 4 is a rear exploded perspective view of a display device according to an embodiment.

FIG. 5 shows an example of a cross section taken along A-A′ of FIG. 1 according to an embodiment.

FIG. 6 shows rear sides of a front chassis, a chassis connecting member, and a bottom frame in a display device according to an embodiment.

FIG. 7 is an exploded view of the front chassis, the chassis connecting member, and the bottom frame shown in FIG. 6 according to an embodiment.

FIG. 8 is an exploded view of D of FIG. 7, showing a chassis connecting member at another angle according to an embodiment.

FIG. 9 shows cross sections of a front chassis and a chassis connecting member before a sliding protrusion is inserted into a sliding groove, in a display device according to an embodiment.

FIG. 10 shows cross sections of a front chassis and a chassis connecting member after a sliding protrusion is inserted into a sliding groove, in a display device according to an embodiment.

FIG. 11 shows a state before a chassis connecting member slides on a front chassis, in a display device according to an embodiment.

FIG. 12 shows a state after a chassis connecting member slides on a front chassis, in a display device according to an embodiment.

FIG. 13 is a cross-sectional perspective view before a chassis connecting member slides on a front chassis, in a display device according to an embodiment.

FIG. 14 is a cross-sectional perspective view after a chassis connecting member slides on a front chassis, in a display device according to an embodiment.

FIG. 15 is an enlarged view of C of FIG. 3 according to an embodiment.

FIG. 16 is an enlarged view of E of FIG. 7 according to an embodiment.

FIG. 17 shows a state after a chassis connecting member is coupled to a front chassis, in FIG. 16 according to an embodiment.

FIG. 18 shows a state after a bottom frame is coupled to the front chassis and the chassis connecting member, in FIG. 17 according to an embodiment.

FIG. 19 is an enlarged view of F of FIG. 18 according to an embodiment.

FIG. 20 shows an example of a cross section taken along B-B′ of FIG. 1 according to an embodiment.

FIG. 21 shows a bottom frame and a printed circuit board mounted on the bottom frame, in a display device according to an embodiment.

FIG. 22 shows a cross section of a display device according to an embodiment.

FIG. 23 is a front view of a rear chassis, a panel holder, and a chassis connecting member in a display device according to an embodiment.

FIG. 24 is an enlarged view of G of FIG. 23 according to an embodiment.

FIG. 25 is a rear view of a rear chassis, a panel holder, and a chassis connecting member in a display device according to an embodiment.

FIG. 26 is an enlarged view of J of FIG. 25 according to an embodiment.

FIG. 27 shows a cross section taken along H-H′ of FIG. 24 according to an embodiment.

FIG. 28 shows a cross section taken along I-I′ of FIG. 24 according to an embodiment.

FIG. 29 shows a state in which a first holder protrusion of a panel holder is inserted into a protrusion hole of a rear chassis, in a display device according to an embodiment.

FIG. 30 shows a state in which a panel holder rotates with respect to a rear chassis, in a display device according to an embodiment.

FIG. 31 shows a state in which a second holder protrusion of a panel holder is engaged with a holder fixing protrusion of a chassis connecting member, in a display device according to an embodiment.

FIG. 32 shows a cross section of a display device according to an embodiment.

FIG. 33 shows a cross section of a display device according to an embodiment.

### MODES OF THE INVENTION

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, the term “and/or” includes any and all combinations of one or more of associated listed items.

Terms such as “1st”, “2nd”, or “first” or “second” may be used simply to distinguish a component from other components, without limiting the component in other aspects (e.g., importance or order).

A certain (e.g., a first) component is referred to as “coupled” or “connected” with or without the terms “functionally” or “communicatively” to another (e.g., second) component. When mentioned, it means that any of the above components can be connected to the other components directly (e.g., by wire), wirelessly, or via a third component.

It will be understood that when the terms “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

It will be understood that when a certain component is referred to as being “connected to”, “coupled to”, “supported by” or “in contact with” another component, it can be directly or indirectly connected to, coupled to, supported by, or in contact with the other component. When a component is indirectly connected to, coupled to, supported by, or in contact with another component, it may be connected to, coupled to, supported by, or in contact with the other component through a third component.

It will also be understood that when a component is referred to as being “on” or “over” another component, it can be directly on the other component or intervening components may also be present.

Meanwhile, in the following description, the terms “up-down direction”, “lower side”, “front-rear direction”, etc. are defined based on the drawings, and the shapes and positions of the components are not limited by the terms.

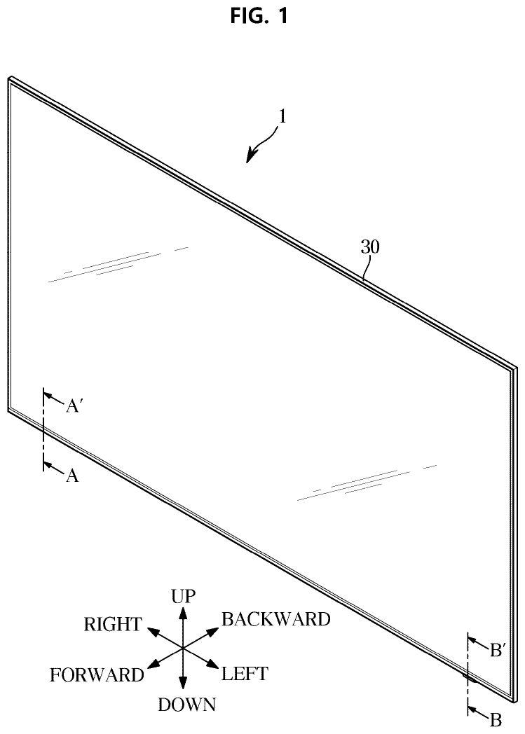

FIG. 1 is a front perspective view of a display device according to an embodiment.

Referring to FIG. 1, a display device 1 may process an image signal received from outside and visually display a processed image. Hereinafter, the display device 1 is assumed to be a television (TV). However, the display device 1 may be implemented as one of various devices, such as a monitor, a portable multimedia apparatus, a portable communication apparatus, etc. That is, a kind of the display device 1 is not limited as long as the display device 1 is capable of visually displaying images.

Also, the display device 1 may be a large format display (LFD) that is installed in an outdoor space, such as the top of building or a bus stop. The outdoor space is not limited to an open-air space, and the display device 1 according to an embodiment may be installed in any place where many peoples enter, such as a subway station, a shopping mall, a theater, an office, a store, etc., although the place is an indoor space.

The display device 1 may receive content including a video signal and an audio signal from various content sources, and output video and audio corresponding to the video signal and the audio signal. For example, the display device 1 may receive content data through a broadcasting reception antenna or a wired cable, receive content data from a content reproducing device, or receive content data from a content providing server of a content provider.

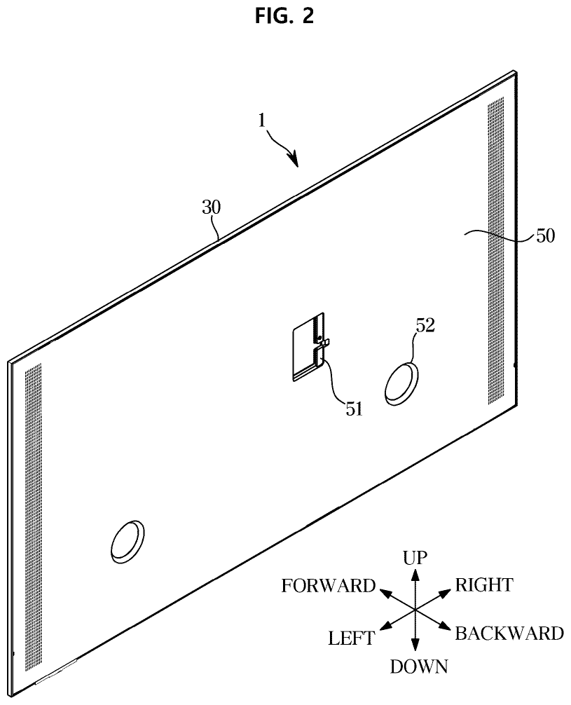

FIG. 2 is a rear perspective view of a display device according to an embodiment.

Referring to FIG. 2, a rear appearance of the display device 1 may be formed by a rear cover 50.

According to an embodiment, the display device 1 may have a constant thickness over an entire area. Any area of a rear side of the display device 1 may not be thicker than the remaining area. The display device 1 may have a constant thickness without an area or configuration that protrudes rearward from the rear side.

Referring to FIG. 2, in the rear side of the display device 1, a connector 51 may be provided to connect to another device provided outside the display device 1. For example, another device provided outside the display device 1 may include a power supply (not shown).

In the rear cover 50, a speaker hole may be provided. Sound from a speaker (not shown) may be emitted to outside of the display device 1 through the speaker hole 52.

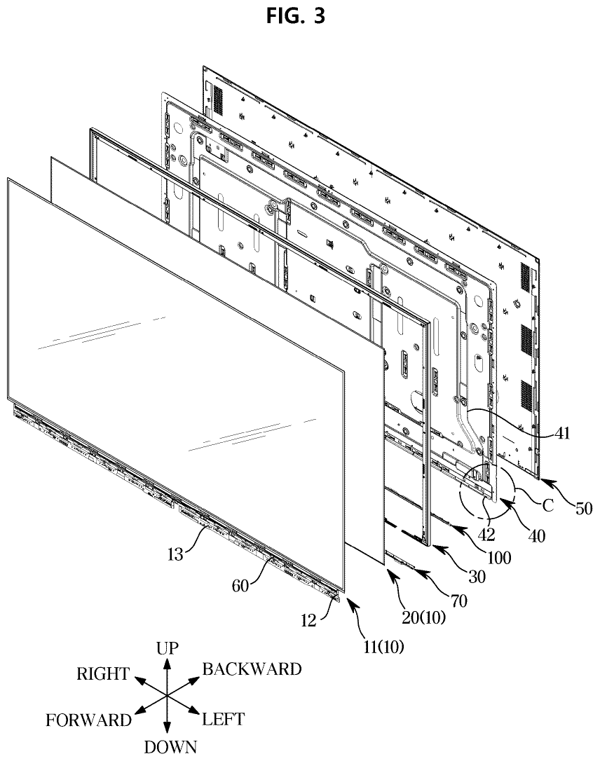

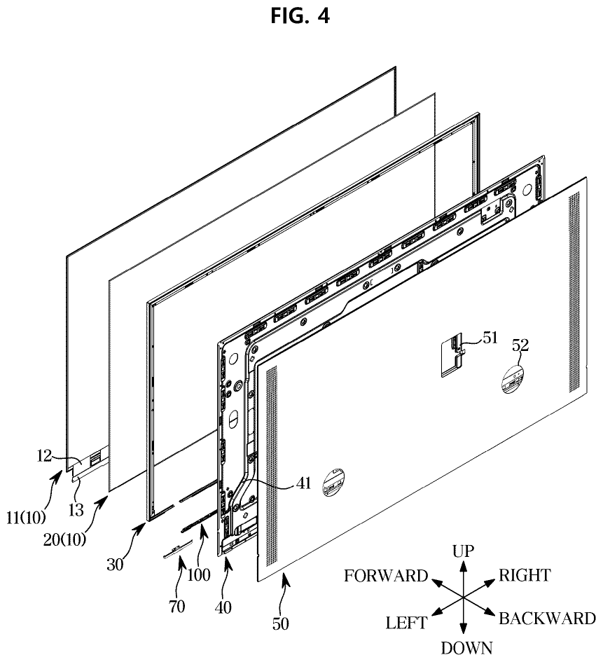

FIG. 3 is a front exploded perspective view of a display device according to an embodiment. FIG. 4 is a rear exploded perspective view of a display device according to an embodiment.

Referring to FIGS. 3 and 4, the display device 1 according to an embodiment may include a display panel 10, a front chassis 30 extending along a perimeter of the display panel 10 and covering sides of the display panel 10, a rear chassis 40 covering a rear surface of the display panel 10, and a rear cover 50 covering a rear surface of the rear chassis 40.

According to an embodiment, the display panel 10 may include a self-emissive panel 11 configured to itself emit light and display images, and a heat dissipation sheet 20 attached on a rear surface of the self-emissive panel 11 and configured to dissipate heat. The heat dissipation sheet 20 may have a size corresponding to the self-emissive panel 11 and may be attached on the rear surface of the self-emissive panel 11 by an adhesive member, such as an adhesive or a double-sided tape.

The self-emissive panel 11 may be configured to display images by using an Organic Light emitting Device (OLED). Because the self-emissive panel 11 does not include a backlight unit, the self-emissive panel 11 may have a smaller thickness than a non-emissive panel.

According to an embodiment, a film cable 12 may be provided in a lower end of the self-emissive panel 11. The film cable 12 may be coupled in a form of a Chip On Film (COF) to the self-emissive panel 11. The film cable 12 may be made of a flexible material to be bent. One end of the film cable 12 may be connected to the lower end of the self-emissive panel 11, and another end of the film cable 12 may be bent to be adjacent to a rear surface of the heat dissipation sheet 20.

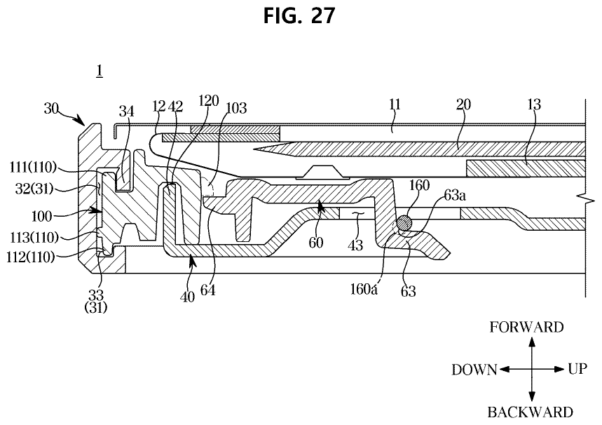

At the other end of the film cable 12, a substrate 13 (see FIG. 27) may be provided. The substrate 13 may be configured to transmit a signal to drive the self-emissive panel 11. The substrate 13 may be coupled to the rear surface of the heat dissipation sheet 20. The substrate 13 may be attached on the rear surface of the heat dissipation sheet 20 by an adhesive member, such as an adhesive or a double-sided tape.

The number of the substrate 13 may depend on a size of the self-emissive panel 11. As the size of the self-emissive panel 11 increases, the number of the substrate 13 may increase. According to an embodiment, the display device 1 may include a pair of substrates 13.

The heat dissipation sheet 20 may be attached on the rear surface of the self-emissive panel 11 to dissipate heat. The heat dissipation sheet 20 may increase a contact area with the self-emissive panel 11 to effectively absorb heat from the self-emissive panel 11. To this end, the heat dissipation sheet 20 and the self-emissive panel 11 may be coupled with each other by an adhesive member.

The heat dissipation sheet 20 may be configured by including at least one of graphite, aluminum, or copper. Preferably, the heat dissipation sheet 20 may be formed by including graphite.

According to an embodiment, the heat dissipation sheet 20 may be separable from the rear chassis 40. In other words, the heat dissipation sheet 20 may not be coupled to the rear chassis 40. Accordingly, the heat dissipation sheet 20 may be separated from the rear chassis 40, and the self-emissive panel 11 adhered on the heat dissipation sheet 20 may also be separated from the rear chassis 40. Because the display panel 10 is separable from the rear chassis 40, the display panel 10 may be easily replaced or repaired.

A panel holder 60 may be coupled to the rear surface of the display panel 10. The panel holder 60 may be attached on the rear surface of the display panel 10 by an adhesive member provided between film cables 12 adjacent to each other. The adhesive member may include an adhesive and a double-sided tape.

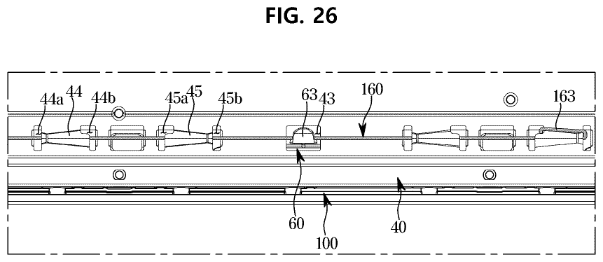

The panel holder 60 may couple the display panel 10 to the rear chassis 40. More specifically, by coupling the panel holder 60 to the rear chassis 40, the display panel 10 may be supported by the rear chassis 40. The panel holder 60 may be coupled to the rear chassis 40 through a wire 160 (see FIG. 26).

The front chassis 30 may cover the sides of the display panel 10. The front chassis 30 may extend along the perimeter of the display panel 10. The front chassis 30 may be provided in a shape of a substantially rectangular ring. The front chassis 30 may not be provided in a closed curve shape but may be provided in an open curve shape.

The front chassis 30 may be made of a metal material. The front chassis 30 may be formed by extruding and bending a metal base material. The front chassis 30 may have a shape in which a lower side is partially cut off. In other words, the front chassis 30 may include a cut portion 36 in the lower side.

The front chassis 30 may protect the display panel 10 and form a side appearance of the display device 1 by covering the sides of the display panel 10.

A chassis connecting member 100 may be coupled to the lower side of the front chassis 30 covering the lower side of the display panel 10. The chassis connecting member 100 may connect the rear chassis 40 to the front chassis 30 to couple the rear chassis 40 to the front chassis 30. The chassis connecting member 100 may be coupled to the front chassis 30 without a separate fastening member by sliding on the lower side of the front chassis 30. This will be described below.

A bottom frame 70 may be provided below the cut portion 36 of the front chassis 30. The bottom frame 70 may cover the cut portion 36. The bottom frame 70 may be elastically coupled to the front chassis 30 and the chassis connecting member 100 without a separate fastening member. This will be described later.

The rear chassis 40 may have a size corresponding to the display panel 10. The rear chassis 40 may cover the rear surface of the display panel 10.

According to an embodiment, the rear chassis 40 may include a bead 41. The bead 41 may be formed by a portion of the rear chassis 40 sunken or protruding. The bead 41 may reinforce rigidity of the rear chassis 40.

The rear chassis 40 may include a coupling rib 42 formed by bending a lower end portion toward a front direction. The coupling rib 42 will be described below.

The rear chassis 40 may be made of a metal material. The rear chassis 40 may be formed by pressing and/or bending a metal base. Because the rear chassis 40 is made of a metal material having high thermal conductivity, the rear chassis 40 may quickly release heat generated from the display panel 10 to the outside.

According to an embodiment, because the rear chassis 40 is made of a metal material having high thermal conductivity, the display device 1 may not include a separate inner plate for heat dissipation of the display panel 10. In addition, the display device 1 may not include a separate inner plate for reinforcing rigidity because the rigidity of the display device 1 is improved by the rear chassis 40 including the bead 41.

The rear cover 50 may cover the rear surface of the rear chassis 40. The rear cover 50 may form a rear appearance of the display device 1. The rear cover 50 may be formed by injection molding.

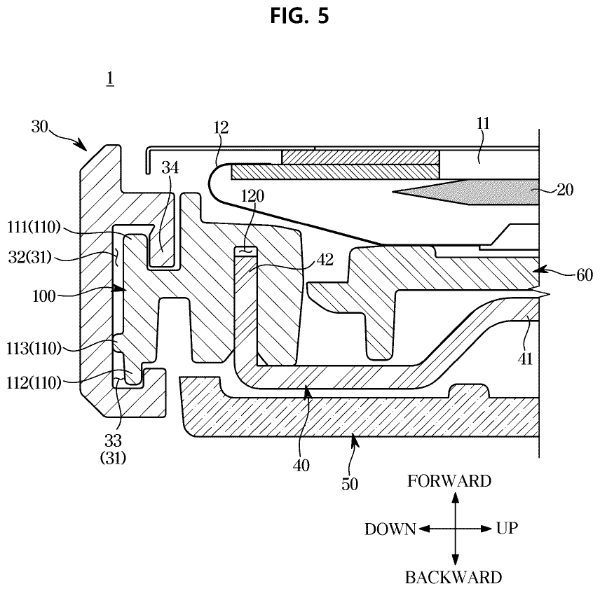

FIG. 5 shows an example of a cross section taken along A-A′ of FIG. 1.

Referring to FIG. 5, a fastening member such as a screw may not be exposed on the front chassis 30. The chassis connecting member 100 may be coupled to the front chassis 30, and the rear chassis 40 may be coupled to the chassis connecting member 100. The chassis connecting member 100 may be coupled to the front chassis 30 without a separate fastening member by sliding on the front chassis 30.

Conventionally, a fastening member has been exposed on a lower surface of a front chassis. Because the lower surface of the front chassis forms a lower appearance of a display device, the fastening member has been exposed on a lower surface of the display device. For example, a head of a screw has been exposed to the lower surface of the display device, which has deteriorated an aesthetic sense of the display device.

Conventionally, a fastening member has been required to couple another component such as a chassis connecting member to a front chassis. The fastening member has been exposed on the lower surface of the display device, which not only has deteriorated design aesthetics, but also has become a factor decreasing productivity.

According to an embodiment, the chassis connecting member 100 may be slidable on the front chassis 30 and may be coupled to the front chassis 30 by sliding on the front chassis 30.

The front chassis 30 may include a sliding groove 31 formed along the lower side of the front chassis 30. The chassis connecting member 100 may include a sliding protrusion 110 that is inserted into the sliding groove 31 and slides within the sliding groove 31. After the sliding protrusion 110 is inserted into the sliding groove 31, the sliding protrusion 110 may slide a preset distance in a first direction in which the sliding groove 31 extends within the sliding groove 31 and, thereby, the chassis connecting member 100 may be coupled to the front chassis 30. The first direction may refer to a right direction denoted in FIGS. 1 to 4.

The front chassis 30 may include the sliding groove 31. The sliding groove 31 may be formed along the lower side of the front chassis 30. The sliding groove 31 may include a first sliding groove 32 and a second sliding hole 33 provided behind the first sliding groove 32.

The front chassis 30 may include a chassis rib 34 forming at least a part of the sliding groove 31 and restricting a movement of the sliding protrusion 110 inserted in the sliding groove 31. The chassis rib 34 may form an upper side of the first sliding groove 31. The chassis rib 34 may restrict the sliding protrusion 110 inserted into the first sliding groove 31 from moving in a second direction that is perpendicular to the first direction. The second direction may refer to an upper direction denoted in FIGS. 1 to 4.

The chassis connecting member 100 may include the sliding protrusion 110. The sliding protrusion 110 may include a first sliding protrusion 111 that is inserted into the first sliding groove 32 and a second sliding protrusion 112 that is inserted into the second sliding groove 33. In addition, the sliding protrusion 110 may include a third sliding protrusion 113 that prevents the sliding protrusion 110 inserted in the sliding groove 31 from moving in upper and lower directions or reduces an amount of upward and downward movements of the sliding protrusion 110.

The first sliding protrusion 111 may be inserted into the first sliding groove 32. An upward movement of the first sliding protrusion 111 inserted in the first sliding groove 32 may be restricted by the chassis rib 34.

The second sliding protrusion 112 may extend rearward from the first sliding protrusion 111. The second sliding protrusion 112 may be inserted into the second sliding groove 33.

The third sliding protrusion 113 may be formed by protruding downward between the first sliding protrusion 111 and the second sliding protrusion 112. The third sliding protrusion 113 may reduce a gap in upper and lower directions of the sliding protrusion 110 within the sliding groove 31.

According to an embodiment, the chassis connecting member 100 may include a coupling groove 120 formed in a rear side of the chassis connecting member 100. The rear chassis 40 may include the coupling rib 42 formed by bending the lower end portion of the rear chassis 40 toward the front direction. The coupling rib 42 may be inserted into the coupling groove 120. By inserting the coupling rib 42 into the coupling groove 120, a lower portion of the rear chassis 40 may be coupled to the chassis connecting member 100 without a separate fastening member. The coupling rib 42 may be fitted into the coupling groove 120.

As described above, the chassis connecting member 100 may be slidingly coupled to the front chassis 30, and the rear chassis 40 may be fitted into the chassis connecting member 100. By coupling the chassis connecting member 100 to the front chassis 30 and coupling the rear chassis 40 to the chassis connecting member 100, the rear chassis 40 may be coupled to the front chassis 30.

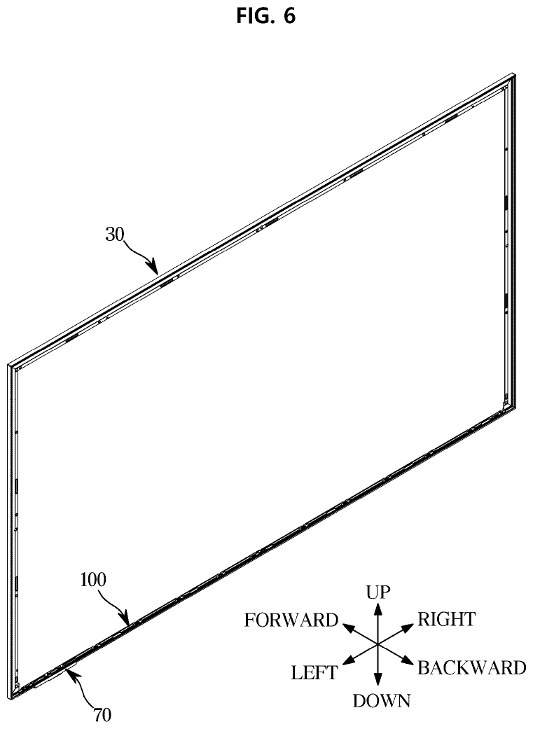

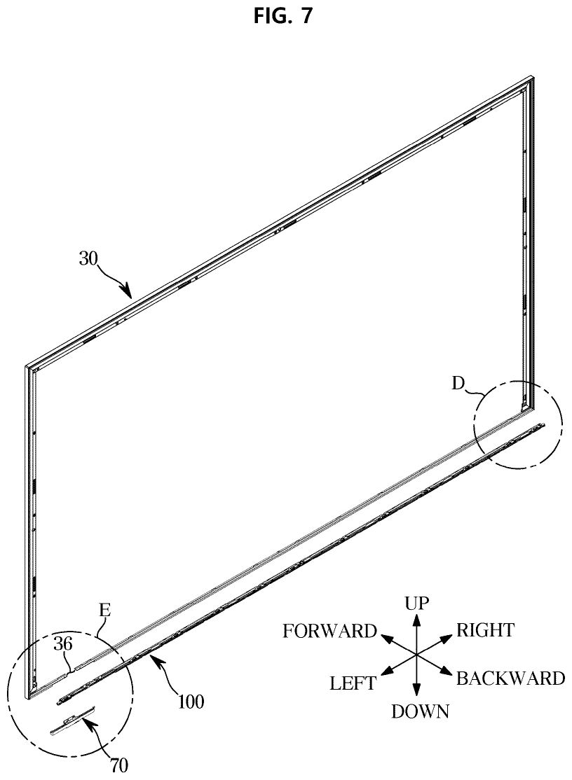

FIG. 6 shows rear sides of a front chassis, a chassis connecting member, and a bottom frame in a display device according to an embodiment. FIG. 7 is an exploded view of the front chassis, the chassis connecting member, and the bottom frame shown in FIG. 6.

Referring to FIGS. 6 and 7, the chassis connecting member 100 may correspond to the lower side of the front chassis 30. The chassis connecting member 100 may be coupled to the lower side of the front chassis 30. At least a portion of the chassis connecting member 100 may be positioned in the cut portion 36 of the front chassis 30. After the chassis connecting member 100 is coupled to the front chassis 30, the chassis connecting member 100 and the front chassis 30 may form a closed curve.

The bottom frame 70 may be positioned below the cut portion 36. The bottom frame 70 may be coupled to the front chassis 30 and the chassis connecting member 100 to cover the cut portion 36 from below. A coupling structure of the bottom frame 70, the front chassis 30, and the chassis connecting member 100 will be described below.

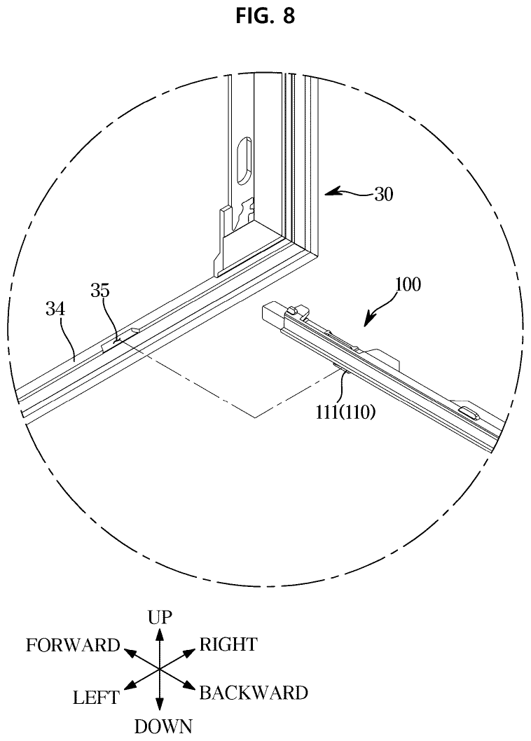

FIG. 8 is an exploded view of D of FIG. 7, showing a chassis connecting member at another angle.

Referring to FIG. 8, the front chassis 30 may include the chassis rib 34 and a protrusion inserting groove 35 formed in the chassis rib 34. Although not shown in FIG. 8, a plurality of protrusion inserting grooves 35 may be provided. The plurality of protrusion inserting grooves 35 may be arranged in such a way as to be spaced apart from each other along a direction in which the chassis rib 34 extends.

The protrusion inserting groove 35 may be formed by cutting at least a portion of the chassis rib 34. The sliding protrusion 110 of the chassis connecting member 100 may be inserted into the sliding groove 31 through the protrusion inserting groove 35.

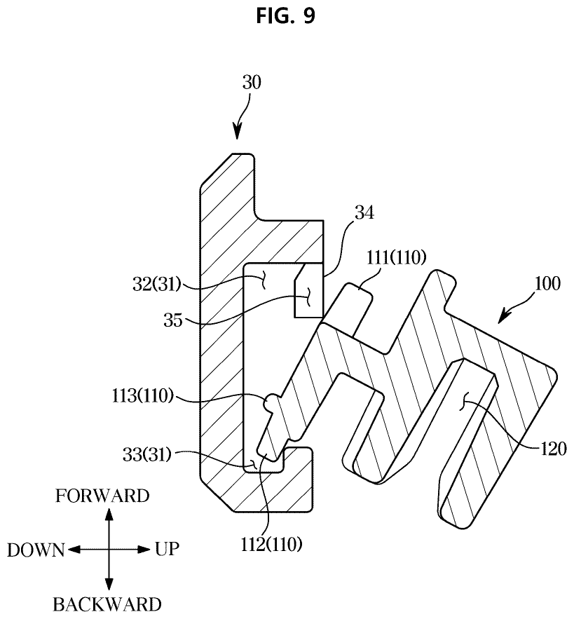

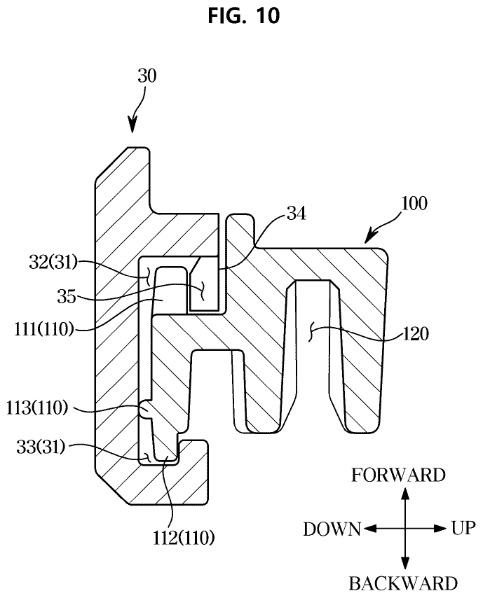

FIG. 9 shows cross sections of a front chassis and a chassis connecting member before a sliding protrusion is inserted into a sliding groove, in a display device according to an embodiment. FIG. 10 shows cross sections of a front chassis and a chassis connecting member after a sliding protrusion is inserted into a sliding groove, in a display device according to an embodiment.

A process of inserting the sliding protrusion 110 of the chassis connecting member 100 into the sliding groove 31 of the front chassis 30 will be described with reference to FIGS. 9 and 10.

Referring to FIG. 9, the second sliding protrusion 112 of the chassis connecting member 100 may be inserted into the second sliding groove 33 of the front chassis 30. Then, by rotating the chassis connecting member 100 in a counterclockwise direction based on FIG. 9 by using the second sliding protrusion 112 as a rotation axis, the first sliding protrusion 111 may be inserted into the first sliding groove 31. However, as shown in FIGS. 9 and 10, because the first sliding protrusion 111 has a structure incapable of passing through the chassis rib 34, the first sliding protrusion 111 may need to pass through the protrusion inserting groove 35 to be inserted into the first sliding groove 32. Referring to FIG. 8, by locating the first sliding protrusion 111 to correspond to the protrusion inserting groove 35, then inserting the second sliding protrusion 112 into the second sliding groove 33 and rotating the chassis connecting member 100, the first sliding protrusion 111 may be inserted into the first sliding groove 32. According to the second sliding protrusion 112 and the first sliding protrusion 111 being respectively inserted into the second sliding groove 33 and the first sliding protrusion 32, it may be considered that the sliding protrusion 110 has been inserted into the sliding groove 31.

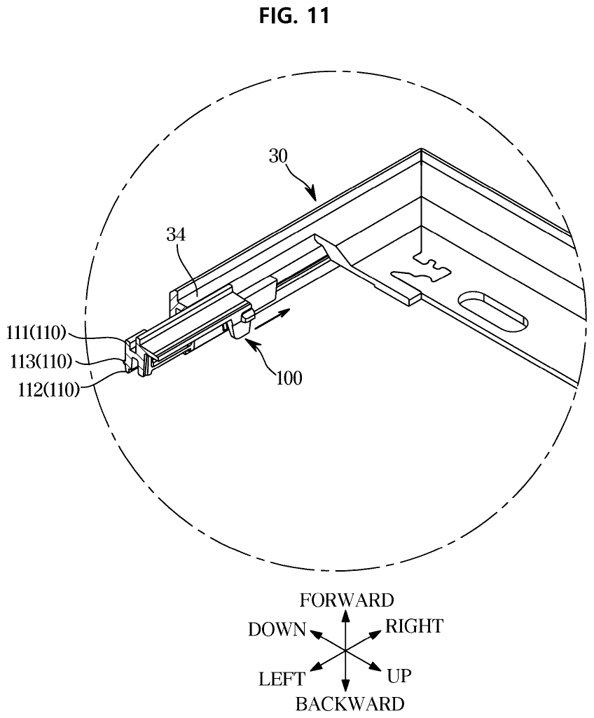

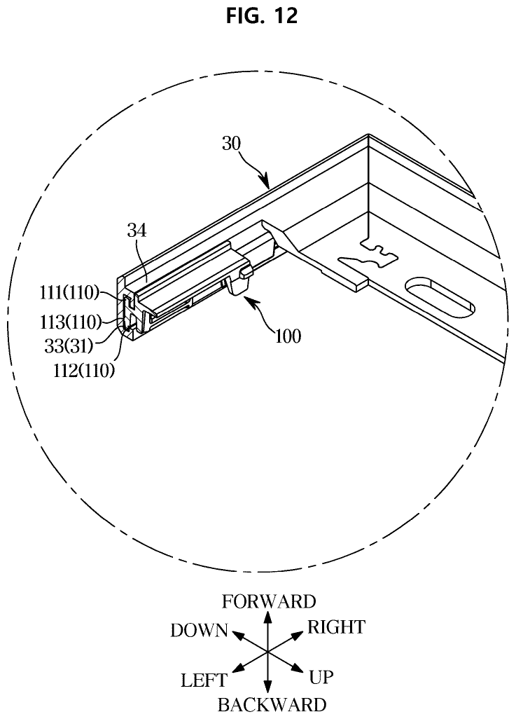

FIG. 11 shows a state before a chassis connecting member slides on a front chassis, in a display device according to an embodiment. FIG. 12 shows a state after a chassis connecting member slides on a front chassis, in a display device according to an embodiment.

Referring to FIGS. 11 and 12, the sliding protrusion 110 inserted into the sliding groove 31 may slide in a first direction. The first direction may refer to a right direction denoted in FIG. 11. According to the sliding protrusion 110 sliding a preset distance in the sliding groove 31 along the first direction, the chassis connecting member 100 may be coupled to the front chassis 30.

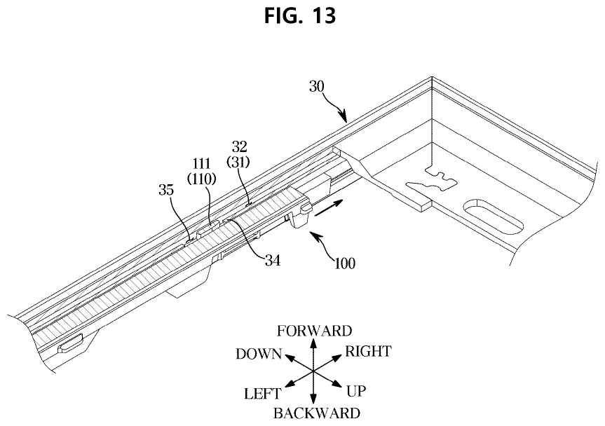

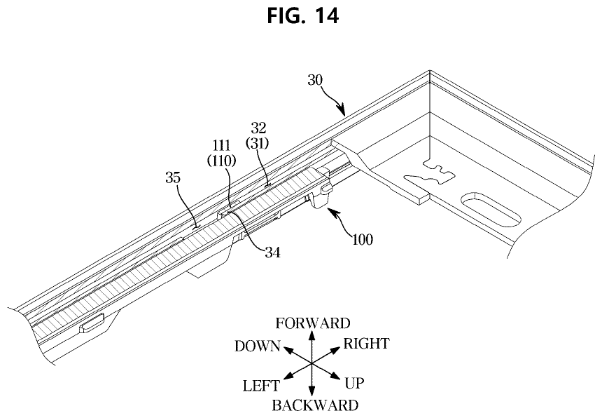

FIG. 13 is a cross-sectional perspective view before a chassis connecting member slides on a front chassis, in a display device according to an embodiment. FIG. 14 is a cross-sectional perspective view after a chassis connecting member slides on a front chassis, in a display device according to an embodiment.

Referring to FIGS. 13 and 14, according to the chassis connecting member 100 sliding in the first direction on the front chassis 30, the first sliding protrusion 111 may be inserted into the first sliding groove 32. The first sliding protrusion 111 inserted in the first sliding groove 32 may be restricted from moving in a second direction that is perpendicular to the first direction, by the chassis rib 34. The second direction may refer to an upper direction denoted in FIGS. 13 and 14.

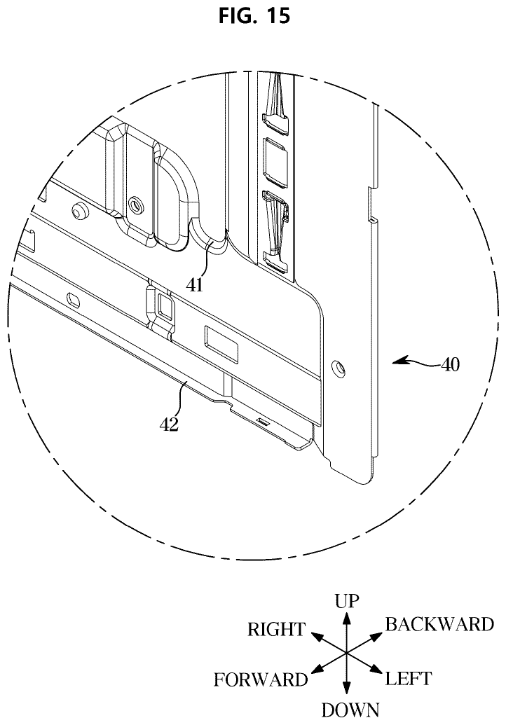

FIG. 15 is an enlarged view of C of FIG. 3.

Referring to FIG. 15, the rear chassis 40 may include the coupling rib 42 formed by bending the lower end portion of the rear chassis 40 in the front direction. The rear chassis 40 may include the bead 41 to reinforce the rigidity of the rear chassis 40.

As described above, the rear chassis 40 may be coupled to the front chassis 30 without a separate fastening member by fitting the connecting rib 42 into the coupling groove 120 of the chassis connecting member 100. More specifically, by inserting the coupling rib 42 into the coupling groove 120, the lower portion of the rear chassis 40 may be coupled to the chassis connecting member 100 without a separate fastening member. As described above, because the chassis connecting member 100 is coupled to the front chassis 30, the rear chassis 40 coupled to the chassis connecting member 100 may be coupled to the front chassis 30.

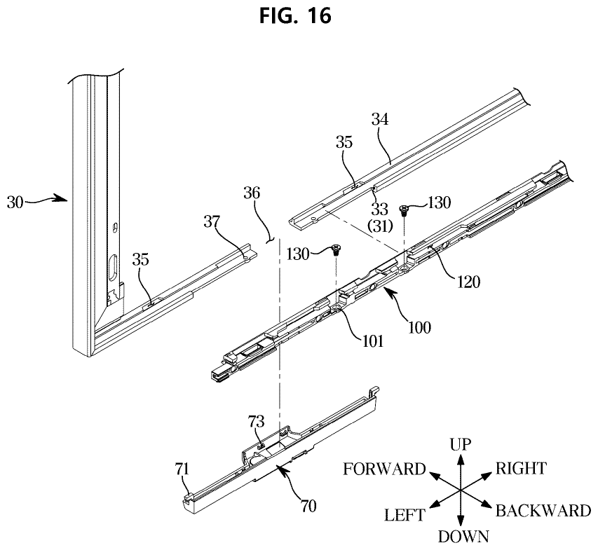

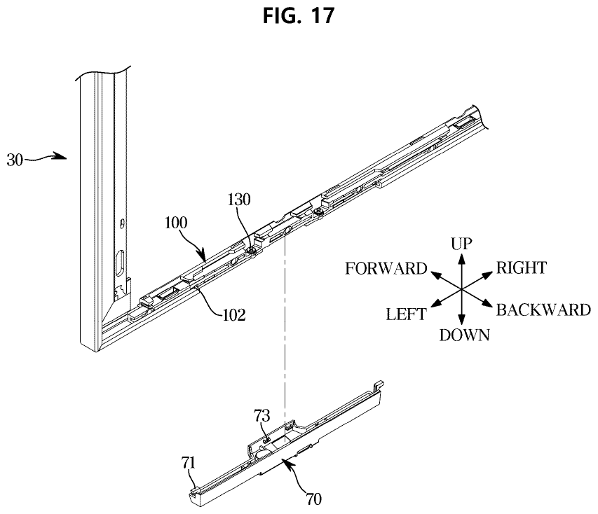

FIG. 16 is an enlarged view of E of FIG. 7. FIG. 17 shows a state after a chassis connecting member is coupled to a front chassis, in FIG. 16.

Referring to FIGS. 16 and 17, the display device 1 may include a fixing member 130 that fixes the chassis connecting member 100 to the front chassis 30 to prevent the chassis connecting member 100 from sliding on the front chassis 30.

The chassis connecting member 100 may be coupled to the front chassis 30 by sliding on the front chassis 30 in the first direction. However, by causing the chassis connecting member 100 to slide in a third direction that is opposite to the first direction, the chassis connecting member 100 may be separated from the front chassis 30. The third direction may refer to a left direction shown in FIGS. 16 and 17.

The front chassis 30 may include a first fixing hole 37 that is adjacent to the cut portion 36. Referring to FIGS. 16 and 17, a pair of first fixing holes 37 may be provided, although not limited thereto. However, one first fixing hole 37 or three or more first fixing holes 37 may be provided.

The chassis connecting member 100 may include a second fixing hole 101 positioned to correspond to the first fixing hole 37 according to the chassis connecting member 100 sliding on the front chassis 30 in the first direction and being coupled to the front chassis 30. Referring further to FIGS. 16 and 17, a pair of second fixing holes 101 may be provided, although not limited thereto. However, one second fixing hole 101 or three or more second fixing holes 101 may be provided.

The fixing member 130 may be inserted into the first fixing hole 37 and the second fixing hole 101. At least a part of the fixing member 130 may pass through the second fixing hole 101 and then pass through the first fixing hole 37. The fixing member 130 may restrict the chassis connecting member 100 from sliding in the first direction or the third direction. Accordingly, the chassis connecting member 100 may be prevented from sliding in the third direction and then being separated from the front chassis 30.

The fixing member 130 may include a screw. Unlike this, the fixing member 130 may include no thread. In this case, the fixing member 130 may include a head portion, and a body portion that has a smaller diameter than the head portion, is inserted into the first fixing hole 37 and the second fixing hole 101, and includes no thread. The body portion may be fitted into the first fixing hole 37 and the second fixing hole 101.

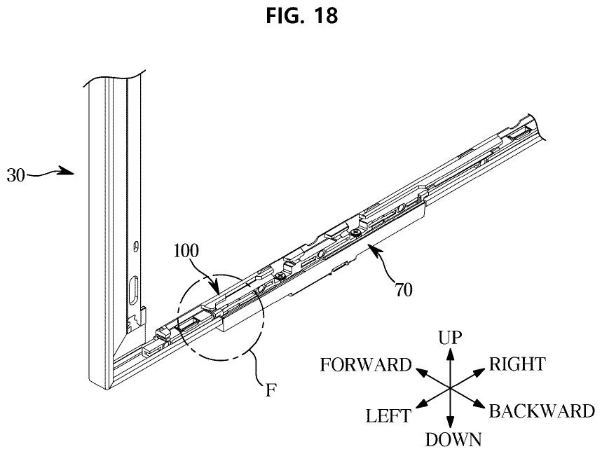

FIG. 18 shows a state after a bottom frame is coupled to the front chassis and the chassis connecting member, in FIG. 17.

Referring to FIGS. 17 and 18, the bottom frame 170 may be coupled to the front chassis 30 and the chassis connecting member 100 to cover the cut portion 36 from below. The bottom frame 170 may prevent the cut portion 36 and the fixing member 130 from being exposed to outside of the front chassis 30. In other words, the bottom frame 170 may cover the cut portion 36 and the fixing member 130 from below such that the cut portion 36 and the fixing member 130 is not visible from a lower surface of the display device 1. The bottom frame 70 may be coupled to the front chassis 30 and the chassis connecting member 100 through a coupling protrusion 71 and an elastic protrusion 73 without a fastening member.

The bottom frame 70 may form a lower appearance of the display device 1 together with the front chassis 30. As described above, on a lower surface of the front chassis 30, no fastening member may be provided except for the fixing member 130. On a lower surface of the bottom frame 70, no fastening member may be provided, and the bottom frame 70 may cover the fixing member 130 and be coupled to the front chassis 30 and the chassis connecting member 100 without a fastening member. Therefore, no fastening member may be exposed on the lower surface of the display device 1. Therefore, design aesthetics of the display device 1 may be improved.

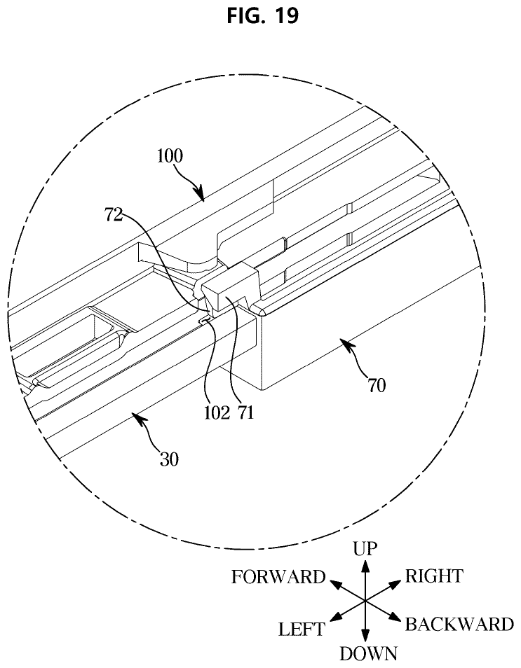

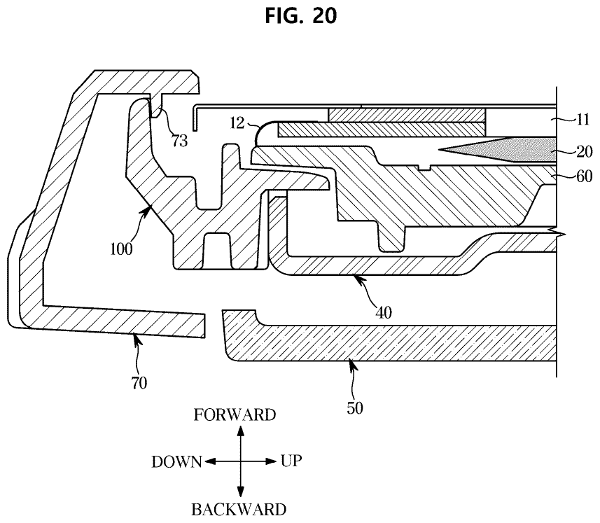

FIG. 19 is an enlarged view of F of FIG. 18. FIG. 20 shows an example of a cross section taken along B-B′ of FIG. 1.

Referring to FIGS. 19 and 20, the bottom frame 70 may be elastically coupled to the front chassis 30 and the chassis connecting member 100 without a separate fastening member.

The bottom frame 70 may include a pair of coupling protrusions 17 provided at both sides of the bottom frame 70. Each of the pair of coupling protrusions 71 may include an insertion protrusion 72 extending downward. The insertion protrusion 72 may be inserted into an insertion groove 102 formed by the front chassis 30 and the chassis connecting member 100.

According to the pair of insertion protrusions 72 being inserted into the pair of insertion holes 102, a rear side of the bottom frame 70 may be fixed to the front chassis 30 and the chassis connecting member 100.

Referring to FIG. 20, according to the elastic protrusion 73 provided on a front side of the bottom frame 70 being caught by the chassis connecting member 100, the front side of the bottom frame 70 may be fixed to the front chassis 30 and the chassis connecting member 100. According to the elastic protrusion 73 being positioned on an upper side of the chassis connecting member 100, the elastic protrusion 73 may be caught by the chassis connecting member 100. According to the bottom frame 70 and the elastic protrusion 73 being elastically deformed, the elastic protrusion 73 may move from a lower side of the chassis connecting member 100 to the upper side of the chassis connecting member 100. In this case, the upper and lower directions may be defined based on directions denoted in FIG. 20.

According to the rear side of the bottom frame 70 and the front side of the bottom frame 70 being respectively fixed to the front chassis 30 and the chassis connecting member 100, the bottom frame 70 may be coupled to the front chassis 30 and the chassis connecting member 100. As described above, the bottom frame 70 may be coupled to the front chassis 30 and the chassis connecting member 100 without a fastening member.

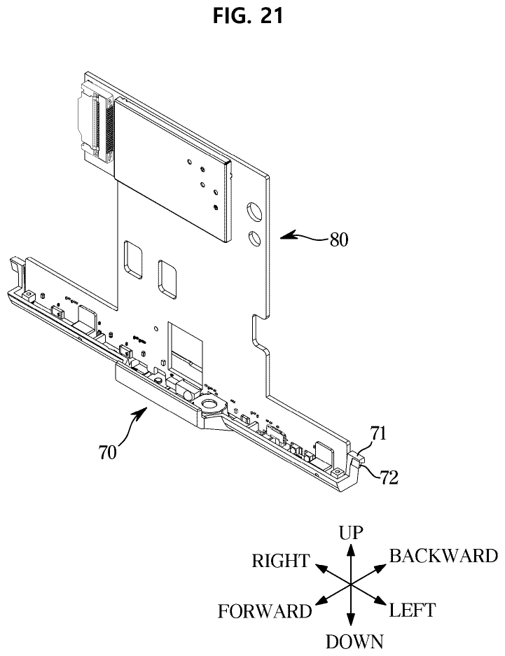

FIG. 21 shows a bottom frame and a printed circuit board mounted on the bottom frame, in a display device according to an embodiment.

Referring to FIG. 21, a printed circuit board 80 may be mounted on the bottom frame 70. In other words, the bottom frame 70 may support the printed circuit board 80. According to the bottom frame 70 being coupled to the front chassis 30 and the chassis connecting member 100, the printed circuit board 80 may face the rear chassis 40 behind the rear chassis 40. Various elements or chips may be mounted on the printed circuit board 80. For example, a chip for receiving a signal from a remote controller may be mounted on the printed circuit board 80.

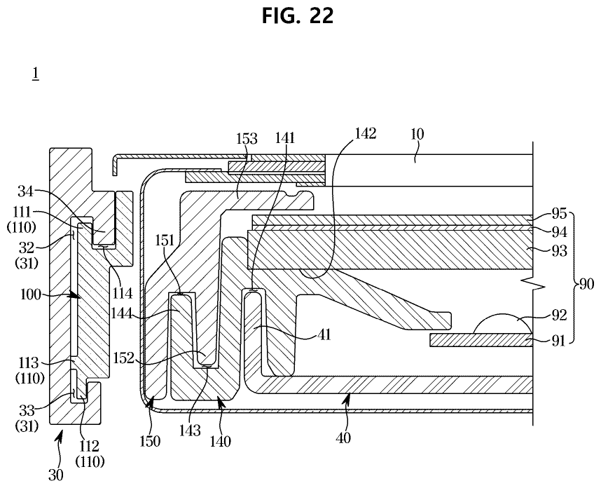

FIG. 22 shows a cross section of a display device according to an embodiment.

Referring to FIG. 22, the display device 1 according to an embodiment may include a display panel 10 which is a non-emissive panel, and a backlight unit 90 which supplies light to the display panel 10.

According to an embodiment, the backlight unit 90 may include a substrate 91, a plurality of light-emitting diodes 92 mounted on the substrate 91, and optical members 93, 94, and 95 positioned on a moving path of light emitted from the plurality of light-emitting diodes 92.

The optical members 93, 94, and 95 may include a diffuser plate 93 that evenly diffuses irregular light emitted from the plurality of light-emitting diodes 92, and a first optical sheet 94 and a second optical sheet 95 that improve properties of light.

The diffuser plate 93 may evenly diffuse irregular light emitted from the plurality of light-emitting diodes 92. The diffuser plate 93 may evenly diffuse light incident onto a rear surface 93a of the diffuser plate 93 and emit the diffused light from a front surface 93b of the diffuser plate 93.

The first optical sheet 94 and the second optical sheet 95 may be positioned in front of the diffuser plate 93 to improve optical properties of light emitted from the diffuser plate 93. Although the drawing shows the first optical sheet 94 and the second optical sheet 95, the number of the optical sheets may be more or less than two.

The first optical sheet 94 and the second optical sheet 95 may include a diffuser sheet that cancels a pattern of the diffuser plate 93, a prism sheet that focuses light to improve brightness, a protection sheet that protects other optical sheets from an external impact or foreign materials, a dual brightness enhancement film (DBEF) that transmits one polarized light and reflects another polarized light to improve brightness, a complex sheet that evenly diffuses light, and a quantum dot sheet that changes a wavelength of light to improve color reproducibility. Quantum dots, which are semiconductor crystals that emit light and are several nanometers in size, may be dispersed inside the quantum dot sheet. The quantum dots may receive blue light and generate all colors of visible light depending on the sizes. The smaller the size of a quantum dot, the shorter wavelength of light the quantum dot may generate, and the larger the size of a quantum dot, the longer wavelength of light the quantum dot may generate.

The first optical sheet 94, the second optical sheet 95, and the diffuser plate 93 may be integrated into one body. An adhesive may be provided between the first optical sheet 94 and the second optical sheet 95 and between the second optical sheet 95 and the diffuser plate 93, thereby integrating the first optical sheet 94, the second optical sheet 95, and the diffuser plate 93 into one sheet.

The display device 1 may include the display panel 10, the front chassis 30 extending along the perimeter of the display panel 10 and covering the sides of the display panel 10, and the rear chassis 40 covering the rear surface of the display panel.

The rear chassis 40 may be positioned behind the backlight unit 90. The backlight unit 90 may be accommodated between the rear chassis 40, the display panel 10, and the front chassis 30.

The display device 1 may include the chassis connecting member 100 coupled to the front chassis 30 by sliding on the lower side of the front chassis 30.

The display device 1 may include a first middle frame 140 coupled to the rear chassis 40 and supporting rear ends of the optical members 93, 94, and 95, and a second middle frame 150 coupled to the first middle frame 140 and supporting front ends of the optical members 93, 94, and 95.

The front chassis 30 may include the sliding groove 31. The sliding groove 31 may be formed along the lower side of the front chassis 30. The sliding groove 31 may include the first sliding groove 32, and the second sliding hole 33 provided behind the first sliding groove 32.

The front chassis 30 may include the chassis rib 34 forming at least a part of the sliding groove 31 and restricting a movement of the sliding protrusion 110 inserted in the sliding groove 31. The chassis rib 34 may form the upper side of the first sliding groove 31. The chassis rib 34 may restrict the sliding protrusion 110 inserted in the first sliding groove 31 from moving in the second direction that is perpendicular to the first direction. The second direction may refer to an upper direction shown in FIG. 22.

The chassis connecting member 100 may include the sliding protrusion 110. The sliding protrusion 110 may include the first sliding protrusion 111 that is inserted into the first sliding groove 32 and the second sliding projection 112 that is inserted into the second sliding groove 33. In addition, the sliding protrusion 110 may include the third sliding protrusion 113 that prevents the sliding protrusion 110 inserted into the sliding groove 31 from moving in the upper and lower directions or reduces an amount of upward and downward movements of the sliding protrusion 110.

The first sliding protrusion 111 may be inserted into the first sliding groove 32. An upward movement of the first sliding protrusion 111 inserted in the first sliding groove 32 may be restricted by the chassis rib 34.

The second sliding protrusion 112 may extend rearward from the first sliding protrusion 111. The second sliding protrusion 112 may be inserted into the second sliding groove 33.

The third sliding protrusion 113 may be formed by protruding downward between the first sliding protrusion 111 and the second sliding protrusion 112. The third sliding protrusion 113 may reduce a gap in the upper and lower directions of the sliding protrusion 110 within the sliding groove 31.

According to an embodiment, the chassis connecting member 100 may include a chassis rib groove 114 in which the chassis rib 34 is inserted. The chassis rib 34 may be inserted in the chassis rib groove 114.

The first middle frame 140 may include a coupling groove 141 in which the coupling rib 42 formed by bending the lower end portion of the rear chassis 40 toward the front direction is inserted.

The first middle frame 140 may include a first support portion 142 supporting the rear ends of the optical members 93, 94, and 95. More specifically, the first support portion 142 may support a lower end portion of a rear surface of the diffuser plate 93.

The second middle frame 150 may include a second support portion 153 supporting the front ends of the optical members 93, 94, and 95. The second support portion 153 may support a lower end portion of a front surface of the second optical sheet 95.

In other words, lower end portions of the optical members 93, 94, and 95 may be positioned between the first middle frame 140 and the second middle frame 150. The lower end portions of the optical members 93, 94, and 95 may be supported by the first middle frame 140 and the second middle frame 150.

The first middle frame 140 may include a first frame protrusion 144. The second middle frame 150 may include a second frame protrusion 152. Also, the first middle frame 140 may include a first protrusion groove 143 in which the second frame protrusion 152 is inserted. The second middle frame 150 may include a second protrusion groove 151 in which the first frame protrusion 144 is inserted.

Although not shown in FIG. 22, the display device 1 according to an embodiment may include the rear cover that covers the rear side of the rear chassis 40. The rear cover may form the rear appearance of the display device 1 by covering the rear surface of the rear chassis 40.

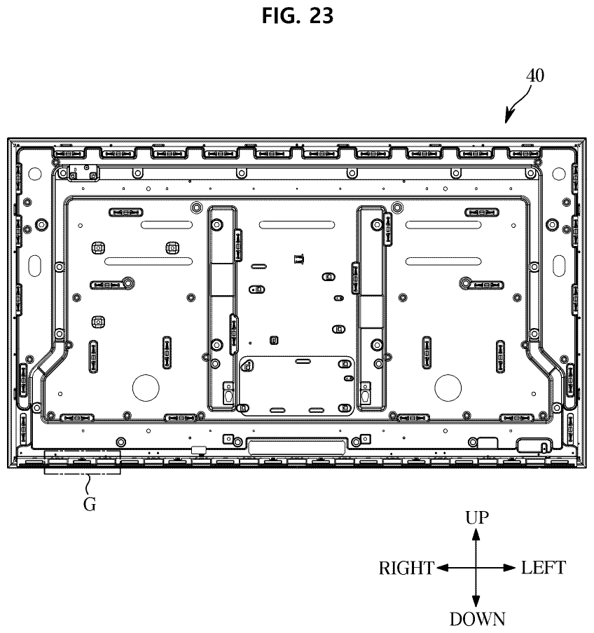

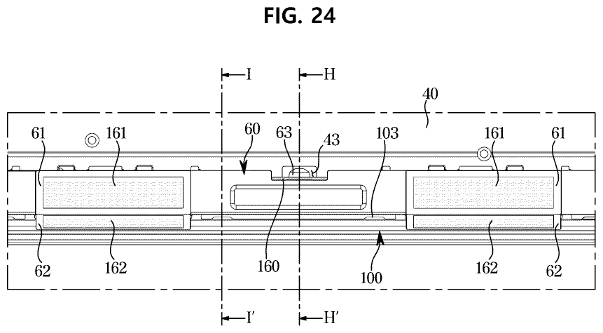

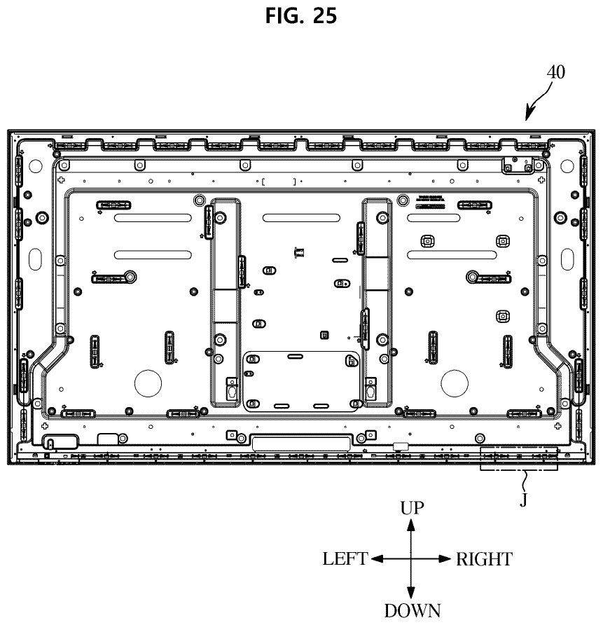

FIG. 23 is a front view of a rear chassis, a panel holder, and a chassis connecting member in a display device according to an embodiment. FIG. 24 is an enlarged view of G of FIG. 23. FIG. 25 is a rear view of a rear chassis, a panel holder, and a chassis connecting member in a display device according to an embodiment. FIG. 26 is an enlarged view of J of FIG. 25.

Referring to FIGS. 24 to 26, the panel holder 60 may be coupled to the rear chassis 40 by the wire 160 and the chassis connecting member 100.

Before the panel holder 60 is coupled to the rear chassis 40, the chassis connecting member 100 may be coupled to the rear chassis 40, as described above. After the chassis connecting member 100 is coupled to the rear chassis 40, the wire 160 may be coupled to the rear chassis 40. Unlike this, after the wire 160 is coupled to the rear chassis 40, the chassis connecting member 100 may be coupled to the rear chassis 40.

As described above, after the chassis connecting member 100 and the wire 160 are coupled to the rear chassis 40, the panel holder 60 may be coupled to the rear chassis 40. A detailed process of coupling the panel holder 60 to the rear chassis 40 will be described below.

Referring to FIGS. 23 and 24, the panel holder 60 may include a first adhesive portion 61, and a second adhesive portion 62 positioned below the first adhesive portion 61. A first adhesive member 161 may be positioned on the first adhesive portion 61, and a second adhesive member 162 may be positioned on the second adhesive portion 62. The first adhesive portion 61 may be an area of the panel holder 60 on which the first adhesive member 161 may be positioned. The second adhesive portion 62 may be an area of the panel holder 60 on which the second adhesive member 162 may be positioned, like the first adhesive portion 61. According to an embodiment, the first adhesive portion 61 and the second adhesive portion 62 may be arranged to be adjacent to each other in the upper and lower directions, and the arrangement may change. Also, only any one of the first adhesive portion or the second adhesive portion may be provided.

A plurality of first adhesive portions 61 may be provided. The plurality of first adhesive portions 61 may be arranged in such a way as to be spaced apart from each other along one direction in which the panel holder 60 extends. The one direction in which the panel holder 60 extends may be a horizontal direction in which a lower edge of the rear chassis 40 extends. In other words, the direction may be a left-right direction.

A plurality of second adhesive portions 62 may be provided. The plurality of second adhesive portions 62 may be arranged in such a way as to be spaced apart from each other along the one direction in which the panel holder 60 extends. The first adhesive portion 61 and the second adhesive portion 62 may be spaced apart from each other in the upper and lower directions.

The first adhesive member 161 may be positioned on the first adhesive portion 61. The second adhesive member 162 may be positioned on the second adhesive portion 62. The first adhesive member 161 and the second adhesive member 162 may include a double-side tape. The first adhesive member 161 and the second adhesive member 162 may adhere a lower edge portion of the display panel 10 to the panel holder 60. A first surface of the first adhesive member 161 may be adhered to the lower edge portion of the display panel 10, and a second surface of the first adhesive member 161 may be adhered to the first adhesive portion 61 of the panel holder 60. Therefore, the first adhesive member 161 may adhere the lower edge portion of the display panel 10 to the panel holder 60. Likewise, a first surface of the second adhesive member 162 may be adhered to the lower edge portion of the display panel 10, and a second surface of the second adhesive member 162 may be adhered to the second adhesive portion 62 of the panel holder 60.

Referring to FIGS. 24 and 26, a first holder protrusion 63 of the panel holder 60 may be positioned between the plurality of first adhesive portions 61 spaced apart from each other along the one direction in which the panel holder 60 extends. The panel holder 60 may be provided with a plurality of first holder protrusions 63, and the plurality of first holder protrusions 63 may be spaced apart from each other along the one direction.

The plurality of first holder protrusions 63 may be adjacent to the plurality of first adhesive portions 61. The plurality of first holder protrusions 63 may be adjacent to the plurality of second adhesive portions 62.

The chassis connecting member 100 may be provided with a plurality of holder fixing protrusions 103. The plurality of holder fixing protrusions 103 may be positioned between the plurality of first adhesive portions 61. Any one of neighboring two of the plurality of holder fixing protrusions 103 may be positioned to one side of the first holder protrusion 63, and the remaining one may be positioned to another side of the first holder protrusion 63.

Because the first holder protrusions 63 and the holder fixing protrusions 103 are positioned between the plurality of first adhesive portions 61, the panel holder 60 may be coupled to the rear chassis 40 by using the chassis connecting member 100 and the wire 160 without interference with the first adhesive members 161. Likewise, because the first holder protrusions 63 and the holder fixing protrusions 103 are positioned between the plurality of second adhesive portions 62, the panel holder 60 may be coupled to the rear chassis 40 by using the chassis connecting member 100 and the wire 160 without interference with the second adhesive members 162.

Referring to FIG. 26, the rear chassis 40 may include a protrusion hole 43 in which the first holder protrusion 63 is inserted. The rear chassis 40 may include a first wire hole 44a, a second wire hole 44b, a third wire hole 45a, and a fourth wire hole 45b, through which the wire 160 passes. The rear chassis 40 may include a first wire support portion 44 and a second wire support portion 45, which support the wire 160.

The first holder protrusion 63 of the panel holder 60 may be inserted in the protrusion hole 43. According to the wire 160 being rested on the first holder protrusion 63 protruding from inside of the rear chassis 40 to outside of the rear chassis 40 through the protrusion hole 43, the panel holder 60 may be coupled to the rear chassis 40.

The wire 160 may pass through the first wire hole 44a, the second wire hole 44b, the third wire hole 45a, and the fourth wire hole 45b. A least a part of the wire 160 may be supported by the first wire support portion 44. At least a part of the wire 160 may be supported by the second wire support portion 45. The first wire support portion 44 and the second wire support portion 45 may restrict a rearward movement range of the wire 10.

Referring to FIG. 26, a bent end portion 163 of the wire 160 may restrict a lateral movement range of the wire 160. For example, because the bent end portion 163 of the wire 160 is prevented from passing through the fourth wire hole 45b, the wire 160 may be restricted from moving in a direction of passing through the fourth wire hole 45b at the bent end portion 163 of the wire 160.

Only one end portion of the wire 160 may be bent. Another end portion of the wire 160, which is not bent, may pass through the first wire hole 44a, the second wire hole 44b, the third wire hole 45a, and the fourth wire hole 45b. Accordingly, by moving the other end portion of the wire 160, which is not bent, in a direction of passing through the first wire hole 44a, the second wire hole 44b, the third wire hole 45a, and the fourth wire hole 45b, the wire 160 may be separated from the rear chassis 40.

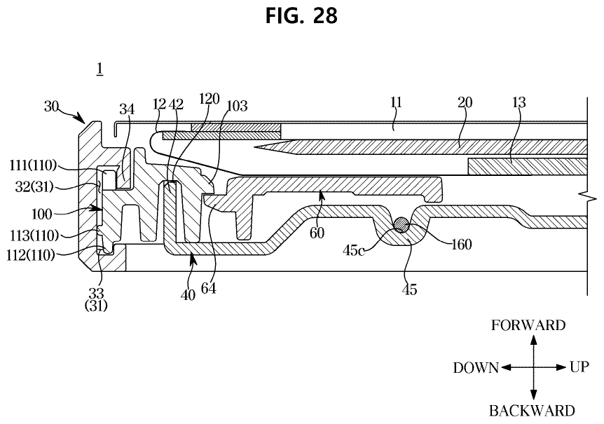

FIG. 27 shows a cross section taken along H-H′ of FIG. 24. FIG. 28 shows a cross section taken along I-I′ of FIG. 24.

Referring to FIGS. 27 and 28, the panel holder 60 may include a second holder protrusion 64. The above-described holder fixing protrusion 103 of the chassis connecting member 100 may fix the second holder protrusion 64. According to the second holder protrusion 64 being engaged with the holder fixing protrusion 101, one side of the panel holder 60 may be fixed. Another side of the panel holder 60 may be fixed by the wire 160. According to the one side of the panel holder 60 being fixed by the fixing protrusion 103 and the second holder protrusion 64 and the other side of the panel holder 60 being fixed by the wire 160 and the first holder protrusion 63, the panel holder 60 may be coupled to the rear chassis 40.

Referring to FIG. 27, according to the panel holder 60 being coupled to the rear chassis 40, the wire 160 may be rested on a wire resting portion 63a of the panel holder 60. The wire 160 may be spaced a small distance from a first position 160a before tension is applied to the wire 160 by the panel holder 60. Therefore, tension may be applied to the wire 160. Due to the tension applied to the wire 160, the first holder protrusion 63 may be coupled to the rear chassis 40 without any gap.

Referring to FIG. 28, at least a part of the wire 160 may be inserted in a wire groove 45c of the second wire support portion 45. According to the at least a part of the wire 160 being inserted in the wire groove 45c, the wire 160 may be restricted from moving in the rear direction. Another part of the wire 160 may be in contact with the rear surface of the rear chassis 40, and therefore, the wire 160 may be restricted from moving in the front direction. That is, according to at least a part of the wire 160 being restricted from moving in the rear direction and another part of the wire 160 being restricted from moving in the front direction, tension may be applied to the wire 160 rested on the wire resting portion 63a of the panel holder 60.

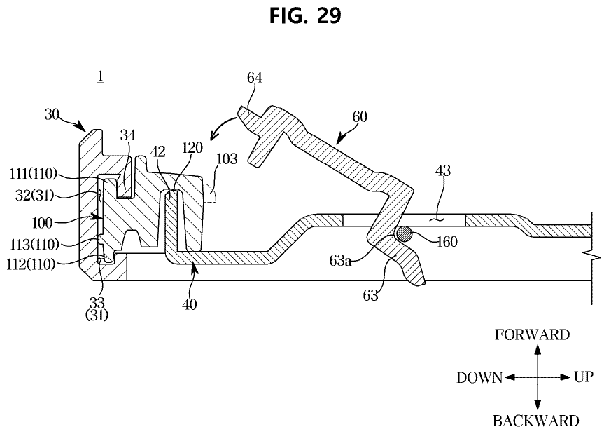

FIG. 29 shows a state in which a first holder protrusion of a panel holder is inserted into a protrusion hole of a rear chassis, in a display device according to an embodiment.

Referring to FIG. 29, to couple the panel holder 60 to the rear chassis 40, the first holder protrusion 63 of the panel holder 60 may be inserted into the protrusion hole 43 of the rear chassis 40. A part of the panel holder 60 may pass through the protrusion hole 43 such that the first holder protrusion 63 and the wire resting portion 63a are positioned behind the rear chassis 40. At this time, tension due to the panel holder 60 may not be applied to the wire 160. Accordingly, the wire 160 may be located at the first position.

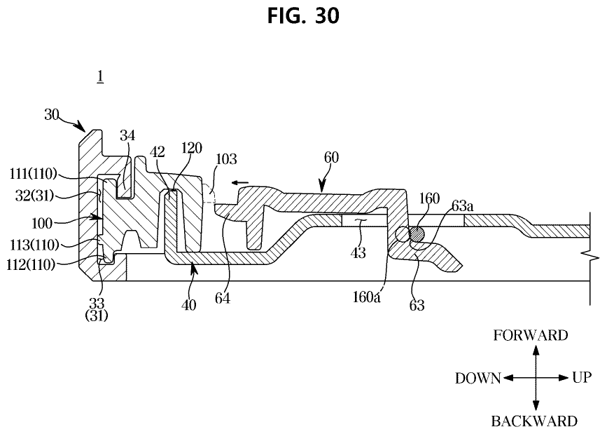

FIG. 30 shows a state in which a panel holder rotates with respect to a rear chassis, in a display device according to an embodiment.

Referring to FIGS. 29 and 30, the wire 160 may be positioned on the wire resting portion 63a, and then, the panel holder 60 may rotate with reference to the rear chassis 40. For the second holder protrusion 64 to pass through the holder fixing protrusion 103, the panel holder 60 may be spaced from the chassis connecting member 100 in the upper and lower directions. Therefore, the wire 160 may be spaced upward from the first position 160a. Because the wire 160 is spaced from the first position 160a, tension may be applied to the wire 160. For example, tension may be applied downward to the wire 160.

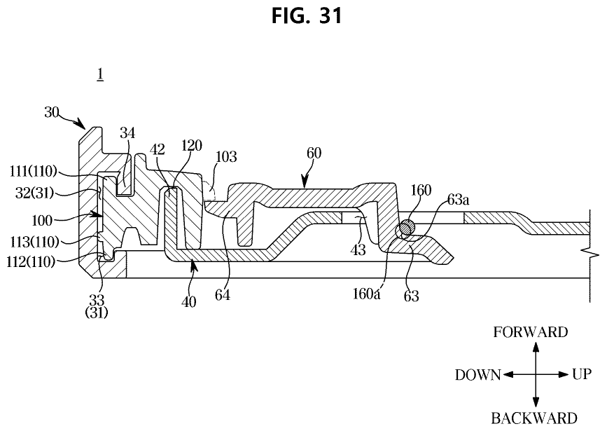

FIG. 31 shows a state in which a second holder protrusion of a panel holder is engaged with a holder fixing protrusion of a chassis connecting member, in a display device according to an embodiment.

Referring to FIGS. 30 and 31, the panel holder 60 may move with respect to the rear chassis 40 to engage the second holder protrusion 64 with the holder fixing protrusion 103. For example, the panel holder 60 may move downward. According to the panel holder 60 moving downward, the second holder protrusion 64 may be engaged with the holder fixing protrusion 103. According to the second holder protrusion 64 being engaged with the holder fixing protrusion 103, one side of the panel holder 60 may be fixed. According to the wire 160 being rested on the wire resting portion 63a of the panel holder 60, another side of the panel holder 60 may be fixed. Accordingly, both sides of the panel holder 60 may be fixed, and the panel holder 60 may be coupled to the rear chassis 40. As described above, according to the panel holder 60 being coupled to the rear chassis 40, the wire 160 may be spaced from the first position 160a. According to the wire 160 being spaced from the first position 160a, tension may be applied to the wire 160. Tension applied to the wire 160 may act as a force of fixing the first holder protrusion 63. Therefore, the panel holder 60 may be coupled to the rear chassis 40 without any gap.

According to an embodiment, the display panel 10 may be separated from the display device 1 without any damage to the display panel 10 and replaced.

To separate the display panel 10 from the display device 1, adhesive members provided on an upper surface and both side surfaces of the display panel 10 may be peeled off, and then, the panel holder 60 provided on a lower surface of the display panel 10 may be separated from the rear chassis 40. After both the display panel 10 and the panel holder 60 are separated from the rear chassis 40, the first adhesive member 161 and the second adhesive member 162 provided on the panel holder 60 may be peeled off, thereby separating the display panel 10 from the panel holder 60. In this process, because the adhesive members provided on an upper edge, both side edges, and a lower edge of the display panel 10 are not forcibly removed, the display panel 10 may be separated from the display device 1 without any damage to the display panel 10.

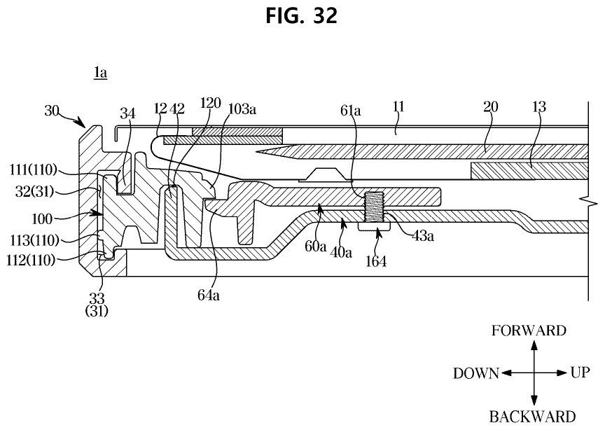

FIG. 32 shows a cross section of a display device according to an embodiment.

Referring to FIG. 32, a display device la according to an embodiment may couple a panel holder 60a to a rear chassis 40a through a fastening member 164.

The fastening member 164 may be a component for coupling the panel holder 60a to the rear chassis 40a, and may include, for example, a screw. Unlike this, the fastening member 164 may include a rivet, an adhesive member, etc.

According to an embodiment, while a holder protrusion 64a is engaged with a holder fixing protrusion 103a, the fastening member 164 may pass through a fastening hole 43a of the rear chassis 40a and be coupled to a fastening groove 61a of the panel holder 60a. The fastening groove 61a may be provided as a hole, unlike as shown in the drawing. The fastening member 164 may couple the panel holder 60a to the rear chassis 40a. One side of the panel holder 60a may be fixed by the holder protrusion 64a and the holder fixing protrusion 103a, and another side of the panel holder 60a may be fixed by the fastening member 164. Because both sides of the panel holder 60a are fixed, the panel holder 60a may be coupled to the rear chassis 40a.

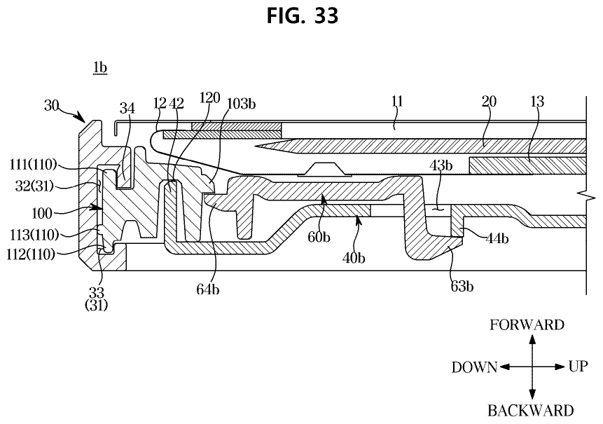

FIG. 33 shows a cross section of a display device according to an embodiment.

Referring to FIG. 33, a panel holder 60b of a display device 1b according to an embodiment may include a first holder protrusion 63b and a second holder protrusion 64b. The first holder protrusion 63b of the panel holder 60b may be engaged with a chassis protrusion 44b of a rear chassis 40b. The second holder protrusion 64b of the panel holder 60b may be engaged with a holder fixing protrusion 103b of the chassis connecting member 100.

According to an embodiment, after the second holder protrusion 64b is engaged with the holder fixing protrusion 103b, the first holder protrusion 63b may be elastically deformed and be engaged with the chassis protrusion 44b. While the second holder protrusion 64b is engaged with the holder fixing protrusion 103b, an external force may be applied to the first holder protrusion 63b to elastically deform the first holder protrusion 63b, thereby causing the first holder protrusion 63b to pass through a protrusion hole 43b.

After the first holder protrusion 63b moves behind the chassis protrusion 44b, the external force applied to the first holder protrusion 63b may be removed. Then, the first holder protrusion 63b may return to an original shape and be engaged with the chassis protrusion 44b. At this time, because an elastic force is applied to the first holder protrusion 63b to return to the original shape, the first holder protrusion 63b may be maintained in a state of being engaged with the chassis protrusion 44b without being separated from the chassis protrusion 44b. Therefore, the panel holder 60b may be coupled to the rear chassis 40b. A display device 1 according to an embodiment may include a display panel 10, a front chassis 30 extending along a perimeter of the display panel and covering sides of the display panel, a rear chassis 40 covering a rear surface of the display panel, and a chassis connecting member 100 connecting the rear chassis to the front chassis to couple the rear chassis to the front chassis. The chassis connecting member may be coupled to the front chassis by sliding on a lower side of the front chassis without a separate fastening member.

The front chassis may include a sliding groove 31 formed along the lower side of the front chassis.

The chassis connecting member may include a sliding protrusion 110 inserted in the sliding groove and configured to slide in the sliding groove.

The chassis connecting member may be coupled to the front chassis by the sliding protrusion being inserted into the sliding groove and sliding a preset distance in a first direction in which the groove extends.

The front chassis may further include a chassis rib 34 forming at least a part of the sliding groove and configured to restrict the sliding protrusion inserted in the sliding groove from moving in a second direction that is perpendicular to the first direction.

The front chassis may further include a protrusion into which the sliding protrusion is inserted.

The front chassis may further include a cut portion 36 formed in the lower side of the front chassis, and a first fixing hole 37 provided adjacent to the cut portion.

The chassis connecting member may further include a second fixing hole 101 positioned to correspond to the first fixing hole when the chassis connecting member is coupled to the front chassis.

The display device may further include a fixing member 130 fixing the chassis connecting member to the front chassis to prevent the chassis connecting member coupled to the front chassis from sliding in the first direction or a second direction which is opposite to the first direction.

The fixing member may be inserted in the first fixing hole and the second fixing hole.

The display device may further include a cover frame 70 covering the cut portion and the fixing member to prevent the cut portion and the fixing member from being exposed to outside of the front chassis.

The cover frame may be elastically coupled to the front chassis and the chassis connecting member without a separate fastening member.

A printed circuit board 80 may be configured to be mounted on the cover frame.

The printed circuit board mounted on the cover frame may face a rear surface of the rear chassis.

The chassis connecting member may include a coupling groove 120 formed in a rear side of the chassis connecting member.

The rear chassis may include a coupling rib 52 formed by bending a lower end portion of the rear chassis toward a front direction.

A lower portion of the rear chassis may be coupled to the chassis connecting member without a separate fastening member according to the coupling rib being inserted into the coupling groove.

The rear chassis may include a bead 41 formed by a portion of the rear chassis sunken or protruding to reinforce rigidity of the rear chassis.

The display device may further include a rear cover 50 coupled to a rear side of the rear chassis and covering a rear surface of the rear chassis, the rear cover forming a rear appearance of the display device.

The display panel may include a self-emissive panel 11 configured to display an image, and a heat dissipation sheet 12 on a rear surface of the self-emissive panel and configured to dissipate heat.

The heat dissipation sheet may include at least one of graphite, aluminum, or copper.

A display device according to an embodiment may include a liquid crystal panel 10, a front chassis 30 extending along a perimeter of the liquid crystal panel and covering sides of the liquid crystal panel, a rear chassis 40 covering a rear surface of the liquid crystal panel, a backlight unit 90 configured to supply light to the liquid crystal panel and accommodated between the liquid crystal panel, the front chassis, and the rear chassis, and a chassis connecting member 100 coupled to the front chassis. The chassis connecting member may be coupled to the front chassis by sliding on a lower side of the front chassis without a separate fastening member.

The front chassis may include a sliding groove 31 formed along the lower side of the front chassis.

The chassis connecting member may include a sliding protrusion 110 inserted in the sliding groove and configured to slide in the sliding groove.

The chassis connecting member 100 may be coupled to the front chassis according to the sliding protrusion being inserted in the sliding groove and sliding a preset distance in a first direction in which the sliding groove extends.

The front chassis may further include a chassis rib 34 forming at least a part of the sliding groove and configured to restrict the sliding protrusion inserted in the sliding groove from moving in a second direction that is perpendicular to the first direction, and a protrusion inserting groove 35 formed in the chassis rib to insert the sliding protrusion into the sliding groove.

The display device may further include a first middle frame 140 coupled to the rear chassis and supporting a rear end of the backlight unit, and a second middle frame 150 coupled to the first middle frame 140 and supporting a front end of the backlight unit.

According to a concept of the present disclosure, there may be provided a display device having an improved aesthetic sense because no fastening member is exposed on a lower surface.

So far, specific embodiments have been shown and described. However, the present disclosure is not limited to the above-described embodiments, and various modifications can be made by one of ordinary skill in the technical art to which the present disclosure belongs without departing from the gist of the technical idea of the present disclosure defined by the claims below.

1. A display device comprising:
a display panel;
a front chassis to extend along a perimeter of the display panel and to cover sides of the display panel;
a rear chassis to cover a rear surface of the display panel; and
a chassis connecting member connectable to the rear chassis so that while the chassis connecting member and the rear chassis are connected, the chassis connecting member couples the rear chassis to the front chassis, wherein the chassis connecting member is coupleable to the front chassis to thereby couple the rear chassis to the front chassis by being slid on a lower side of the front chassis without requiring a separate fastening member.

2. The display device of claim 1, wherein
the front chassis comprises a sliding groove formed along the lower side of the front chassis, and
the chassis connecting member comprises a sliding protrusion insertable in the sliding groove and configured to slide in the sliding groove.

3. The display device of claim 2, wherein
the chassis connecting member is coupled to the front chassis by the sliding protrusion being inserted into the sliding groove and sliding a preset distance along a first direction in which the sliding groove extends.

4. The display device of claim 3, wherein
the front chassis further comprises:
a chassis rib forming at least a part of the sliding groove and configured to restrict the sliding protrusion inserted in the sliding groove from moving along a second direction that is perpendicular to the first direction, and
a protrusion inserting groove formed in the chassis rib into which the sliding protrusion is inserted.

5. The display device of claim 3, wherein
the front chassis further comprises a cut portion formed in the lower side of the front chassis, and a first fixing hole provided adjacent to the cut portion, and
the chassis connecting member further comprises a second fixing hole positioned to correspond to the first fixing hole based on the chassis connecting member being coupled to the front chassis.

6. The display device of claim 5, further comprising:
a fixing member fixing the chassis connecting member to the front chassis to prevent the chassis connecting member coupled to the front chassis from sliding along the first direction or a second direction which is opposite to the first direction,
wherein the fixing member is inserted in the first fixing hole and the second fixing hole.

7. The display device of claim 6, further comprising:
a cover frame covering the cut portion and the fixing member to prevent the cut portion and the fixing member from being exposed outside the front chassis.

8. The display device of claim 7, wherein
the cover frame is elastically coupled to the front chassis and the chassis connecting member without requiring a separate fastening member.

9. The display device of claim 7, wherein
a printed circuit board is configured to be mounted on the cover frame, and
the printed circuit board while mounted on the cover frame faces a rear surface of the rear chassis.

10. The display device of claim 1, wherein
the chassis connecting member comprises a coupling groove formed in a rear side of the chassis connecting member, and
the rear chassis comprises a coupling rib bent at a lower end portion of the rear chassis toward a front direction of the display panel.

11. The display device of claim 10, wherein
a lower portion of the rear chassis is coupled to the chassis connecting member without requiring a separate fastening member based on the coupling rib being inserted into the coupling groove.

12. The display device of claim 1, wherein
the rear chassis comprises a bead formed by a portion of the rear chassis sunken or protruding to reinforce rigidity of the rear chassis.

13. The display device of claim 1, further comprising
a rear cover coupled to a rear side of the rear chassis and covering a rear surface of the rear chassis, the rear cover forming a rear appearance of the display device.

14. The display device of claim 1, wherein
the display panel comprises:
a self-emissive panel configured to display an image, and
a heat dissipation sheet on a rear surface of the self-emissive panel and configured to dissipate heat.

15. The display device of claim 14, wherein
the heat dissipation sheet includes at least one of graphite, aluminum, or copper.
